(19) United States
(12) Patent Application Publication
(10) Pub. No.: US 2018/0241390 A1
(43) Pub. Date: Aug. 23, 2018

(54) REGULATING TRANSISTOR SLOPE

(71) Applicant: SEMICONDUCTOR COMPONENTS INDUSTRIES, LLC, Phoenix, AZ (US)

(72) Inventor: Francois LAULANET, Brussels (BE)

(73) Assignee: SEMICONDUCTOR COMPONENTS INDUSTRIES, LLC, Phoenix, AZ (US)

(21) Appl. No.: 15/440,439

(22) Filed: Feb. 23, 2017

(51) Int. Cl. H03K 17/687; H03K 5/12

(52) U.S. Cl. CPC H03K 17/687; H03K 5/12

(57) ABSTRACT

A circuit for regulating the slope of a transistor includes the transistor and a monitor module coupled to the transistor to evaluate the slope of the transistor. The circuit further includes a comparator coupled the monitor module to compare the slope with a target slope. The circuit further includes a driver coupled to the comparator and the transistor to regulate the slope of the transistor based on output of the comparator by increasing or decreasing voltage supplied to the transistor at most once per pulse cycle until the slope reaches the target slope.

### BACKGROUND

Transistors are ubiquitous, and metal-oxide semiconductor field-effect transistors (“MOSFETs”) are commonly used as a power switching device. A MOSFET device includes a source region, a drain region, a channel region extending between the source and drain regions, and a gate structure provided adjacent to the channel region. The gate structure includes a conductive gate electrode layer disposed adjacent to and separated from the channel region by a thin dielectric layer.

When a MOSFET device is in the on state, a voltage is applied to the gate structure to form a conduction channel region between the source and drain regions, which allows current to flow through the device. In the off state, any voltage applied to the gate structure is sufficiently low so that a conduction channel does not form, and thus current flow does not occur. In the off state, the device may support a high voltage between the source region and the drain region.

Switching between an off state to an on state, or an on state to an off state, is not instantaneous. Rather, some amount of time is necessary for the voltage or current of the device to reach each state from the other, and controlling such time is difficult to achieve without extra circuit elements, known as trimming, which introduce undesirable complexity and cost into the circuity and products containing the device. Additionally, controlling such time is undesirably dependent on temperature, topology, and even package stress.

### SUMMARY

A circuit for regulating the slope of a transistor includes the transistor and a monitor module coupled to the transistor to evaluate the voltage or the current across the transistor. The circuit further includes a comparator coupled the monitor module to compare the voltage or the current across the transistor with a reference current or voltage. The circuit further includes a driver coupled to the comparator and the transistor to regulate a slope of the transistor based on output of the comparator by increasing or decreasing voltage supplied to the transistor at most once per pulse cycle until the slope reaches a target slope.

The comparator may also track a second circuit condition different from the slope such as an under load, an open load, an over voltage load, an over current, and/or a short circuit. The driver may increase voltage or current supplied to the transistor if the slope is less steep than the target slope, and the driver may decrease voltage or current supplied to the transistor if the slope is steeper than the target slope. The circuit may drive a light emitting diode, a motor, or the like. The slope may be a voltage slope or a current slope.

A method of regulating the slope of a transistor includes comparing the slope of the transistor to a target slope using a comparator. The method further includes increasing or decreasing voltage or current supplied to the transistor at most once per pulse cycle until the slope reaches the target slope.

Comparing the slope may also include simultaneously tracking a second circuit condition different from the slope using the comparator. The second circuit condition may be an under load, an open load, an over voltage load, an over current, and/or a short circuit. Increasing or decreasing voltage supplied to the transistor may include increasing voltage or current supplied to the transistor if the slope is less steep than the target slope or decreasing voltage or current supplied to the transistor if the slope is steeper than the target slope. The slope may be a voltage slope or a current slope.

### BRIEF DESCRIPTION OF THE DRAWINGS

Accordingly, systems and methods for regulating transistor slope are disclosed herein. In the drawings:

FIG. 1A is a graph of illustrative variations that may occur to transistor slope;

FIG. 1B is a graph of an illustrative regulation of transistor slope to match a target slope;

FIG. 2 is a circuit diagram illustrating regulation of transistor slope;

FIG. 3 is a circuit diagram illustrating a specific implementation of regulating transistor slope; and

FIG. 4 is a flow diagram of an illustrative method for regulating transistor slope.

It should be understood, however, that the specific embodiments given in the drawings and detailed description thereto do not limit the disclosure. On the contrary, they provide the foundation for one of ordinary skill to discern the alternative forms, equivalents, and modifications that are encompassed together with one or more of the given embodiments in the scope of the appended claims.

### NOTATION AND NOMENCLATURE

Certain terms are used throughout the following description and claims to refer to particular system components and configurations. As one of ordinary skill will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or a direct electrical or physical connection. Thus, if a first device couples to a second device, that connection may be through a direct electrical connection, through an indirect electrical connection via other devices and connections, through a direct physical connection, or through an indirect physical connection via other devices and connections in various embodiments.

### DETAILED DESCRIPTION

Transistor slope is measured in output (voltage or current) per unit time during the transitions between on and off states. The time to reach each state must be within certain tolerances informed by the surrounding circuity and application. A typical general purpose device may have a slope of 5V per microsecond. Low power op-amps may have slopes of 0.5V per microsecond whereas fast op-amps may have slopes of 50V per microsecond or more. However, the variations in slope due to trimming, temperature, topology, package stress, and the like greatly increases the probability that such tolerances will be violated.

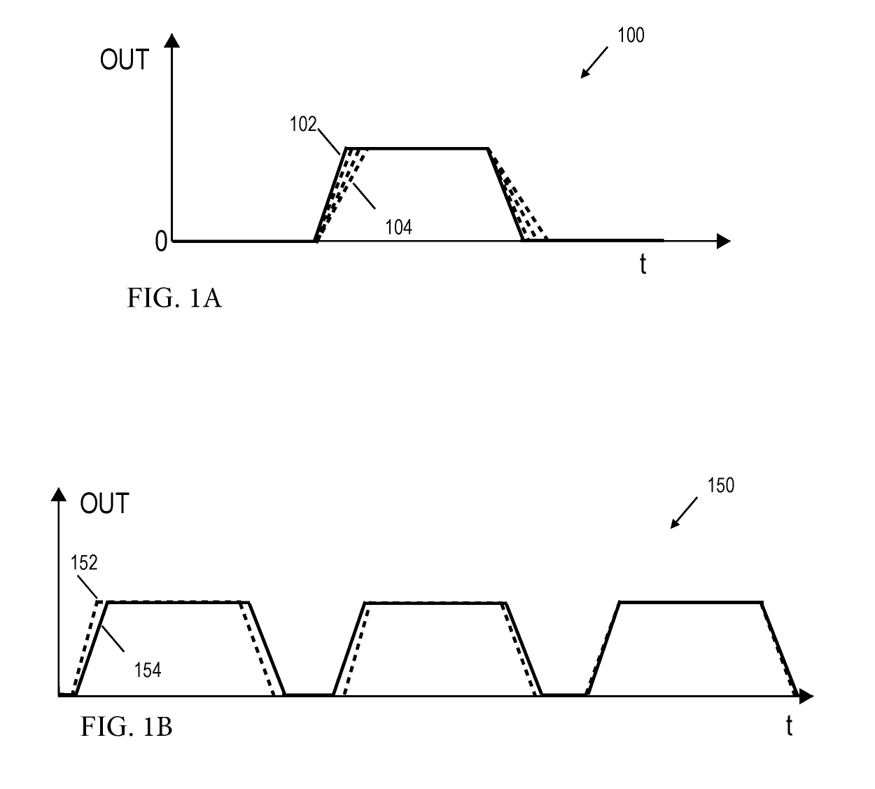

FIG. 1A is a graph 100 of such variations. Specifically, the leftmost curve represents a target slope 102 between the off state (zero ouput) and the on state (80% to 100% output in voltage or current) and vice versa. A 50% output marker is shown on the graph 100 for clarity. The target slope 102 is a predetermined slope that is optimized for ideal timing considering the surrounding circuitry and application. The curves to the right represent possible variations of the actual transistor slope 104 during operation. As can be seen, the variations may be off the target by as much as 3 times, which likely places the transistor out of switching tolerance. Slope regulation will ideally make the transistor slope 104 match the target slope 102 during operation.

FIG. 1B is a graph 150 of regulation of the transistor slope 154 to match the target slope 152. Specifically, during the first pulse cycle or period, shown as the far left pulse, the difference between the transistor slope 154 and the target slope 152 is determined. Here, the transistor slope 154 is less steep than the target slope 152. As such, the current or voltage supplied to the transistor is increased. During the second pulse cycle, shown as the middle pulse, the transistor slope 154 is more steep than the target slope 152, i.e., too much voltage or current was supplied to the transistor. Accordingly, the current or voltage supplied to the transistor is decreased. During the third pulse cycle, shown as the far right pulse, the transistor slope 154 matches the target slope 152, and accordingly no increase or decrease of voltage or current supplied to the transistor occurs. In this way, the slope of a transistor is regulated during operation by increasing or decreasing voltage or current supplied to the transistor at most once per pulse cycle until the transistor slope 154 reaches the target slope 152.

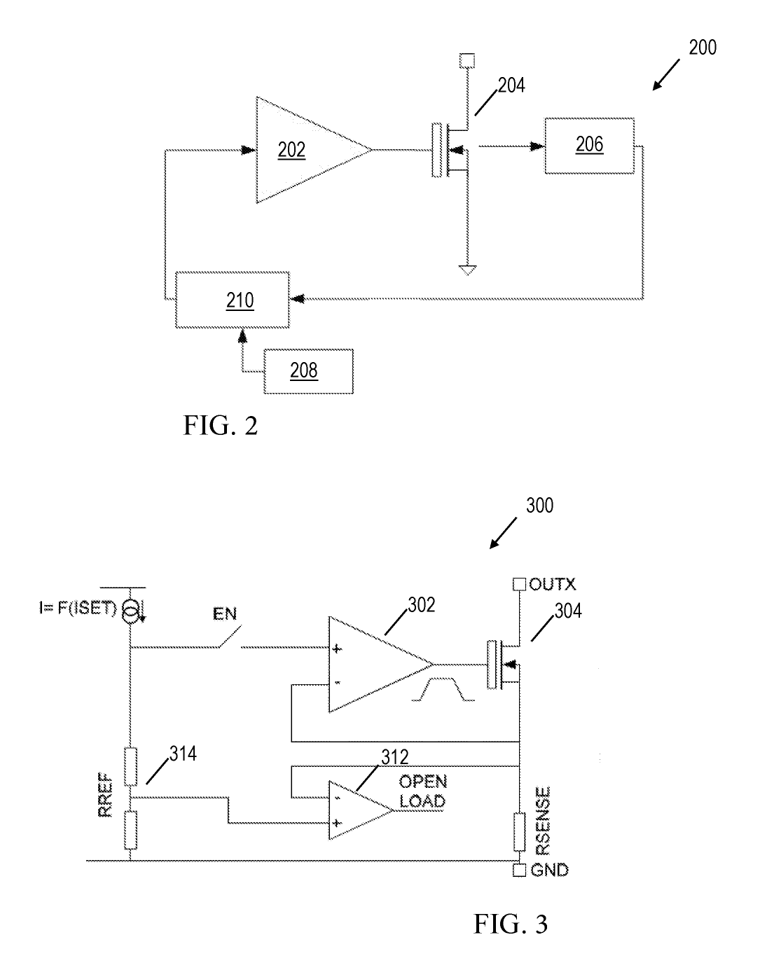

FIG. 2 is a circuit diagram illustrating regulation of transistor slope. The circuit 200 includes a transistor 204 and a monitor module 206 coupled to the transistor 204 to evaluate the voltage or the current across the transistor 204. The current or voltage may be evaluated across any desired portions of the transistor 204, and the transistor 204 may be of any type depending upon the surrounding circuitry and application.

The circuit 200 further includes a comparator 210 coupled the monitor module 206 to compare the voltage or the current across the transistor 204 with one or more reference currents or voltages. The output of the monitor module 206 may be coupled to the input of the comparator 210. The comparator 210 is also coupled to a clock 208, and the output of the clock 208 may be coupled to the input of the comparator 210. The clock 208 may be implemented as a phase locked loop or oscillator in various embodiments, and the clock signal may be used to align the signals of the monitor module 206 and references for comparison purposes. The comparator 210 and clock 208 need not be specifically added or exclusively repurposed to the circuit 200 for purposes of slope regulation. Rather, in most applications sufficient circuitry already exists to implement to comparator 210 and clock 208 during slope regulation alongside their other functions. In this way, excess circuitry that introduces instability to the overall system need not be added to take advantage of slope regulation. Rather, previously existing circuitry may be given extra functionality as elements of slope regulation.

In at least one embodiment, the comparator 210 changes its output depending on whether the output of the monitor module 206 is greater or less than the reference voltage or current at a specific time provided by the clock 208. In some embodiments, the comparator 210 may be relatively simple such as a check for a higher or lower magnitude resulting in a step increase or decrease in current or voltage. In other embodiments, the comparator 210 may be relatively complex such as a microcontroller implementing an algorithm resulting in a multi-step increase or decrease in voltage or current. For example, the comparator 210 is a proportional integral derivative controller in at least one embodiment. The complexity of the comparator 210 may be informed by the needs of the surround circuitry and application.

The circuit 200 further includes a driver 202 coupled to the comparator 210 and the transistor 204 to regulate the slope of the transistor 204 based on output of the comparator 210 by increasing or decreasing voltage or current supplied to the transistor 204 at most once per pulse cycle until the slope reaches the target slope as described above. The output of the comparator 210 may be coupled to the input of the driver 202, while the output of the driver 202 may be coupled to the input of the transistor 204. The input of the transistor 204 may be any portion of the transistor 204 as desired, and the transistor 204 may be of any type. The driver 202 may include or be coupled to a voltage source or current source in order to facilitate such increase or decrease.

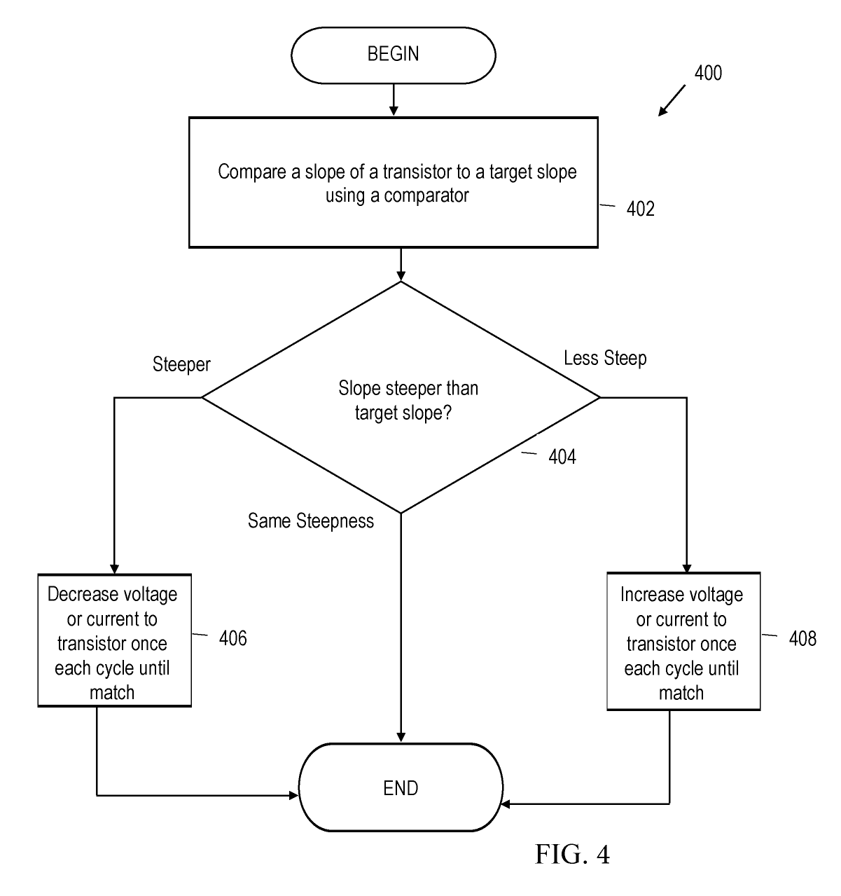

FIG. 3 is a circuit diagram illustrating a specific implementation of regulating the slopes of one or more transistors. The circuit 300 includes a transistor 304, which may output to a coupled monitor module (not shown) to evaluate the voltage and/or current across the transistor 304.

The circuit 300 further includes a comparator 312 to compare the voltage across the RSENSE resistor, with one or more reference voltages 314. The comparator 312 changes its output depending on whether the output of the monitor module is greater or less than the reference voltage. In other embodiments, the comparator 312 changes its output based on a multi-step algorithm informed by the surrounding circuitry and application as described above. The comparator 312 may also track a second circuit condition different from the slopes such as an under load, an open load, an over voltage load, an over current, and/or a short circuit. Here, the comparator 312 is tracking an open load condition. In this way, existing circuitry may be given extra functionality for slope regulation.

The circuit 300 further includes a driver 302 coupled to the comparator 312 and the transistor 304 to regulate a slope of the transistor 304 based on output of the comparator 312 by increasing or decreasing currents and/or voltages supplied to the transistor 304 at most once per pulse cycle until the slope reaches the target slopes. The driver 302 may increase voltage and/or current supplied to the transistor 304 if the slope is less steep than the target slopes, and the driver 302 may decrease voltage and/or current supplied to the transistor 304 if the slope is steeper than the target slope.

The output of the comparator 312 may be coupled to the input of the driver 302, while the output of the driver 302 may be coupled to the input of the transistor 304. The input of the transistor 304 may be any portion of the transistor 304 as desired, and the transistor 304 may be of any type. The circuit 300 may drive a light emitting diode, a motor, or the like.

FIG. 4 is a flow diagram of an illustrative method for regulating transistor slope. At 402, a comparator compares the slope of the transistor to a target slope. Comparing the slope may also include simultaneously tracking a second circuit condition different from the slope using the comparator. The second circuit condition may be an under load, an open load, an over voltage load, an over current, and/or a short circuit.

At 404, if the transistor slope is the same steepness as the target slope, then the method ends. If the transistor slope is steeper than the target slope, then voltage or current supplied to the transistor is decreased at 406 at most once per pulse cycle, or period, until the transistor slope reaches the target slope. If the transistor slope is less steep than the target slope, then voltage or current supplied to the transistor is increased at 408 at most once per pulse cycle, or period, until the transistor slope reaches the target slope. The slope may be a voltage slope or a current slope.

By using the concepts described herein, regulating transistor slope may be achieved without extra circuit elements, which introduce undesirable complexity and cost into the circuity and products containing the device. Additionally, variable temperature, topology, and package stress effects on transistor slope are mitigated or eliminated.

Numerous other modifications, equivalents, and alternatives, will become apparent to those skilled in the art once the above disclosure is fully appreciated. It is intended that the following claims be interpreted to embrace all such modifications, equivalents, and alternatives where applicable.

1. A circuit for regulating a slope of a transistor that drives transitions in an output voltage or current, the circuit comprising:
the transistor;
a monitor module coupled to the transistor to provide a output signal representative of the output voltage or current;
a comparator coupled to the monitor module to compare the output signal with a reference signal at a specific time relative to each of the transitions;
a driver coupled to the comparator and the transistor to regulate the slope of the transistor based on output of the comparator by increasing or decreasing voltage or current supplied to the transistor at most once per pulse cycle until the slope reaches a target slope.

2. The circuit of claim 1, wherein the comparator also tracks a second circuit condition different from the slope.

3. The circuit of claim 2, wherein the second circuit condition is an under load.

4. The circuit of claim 2, wherein the second circuit condition is an open load.

5. The circuit of claim 2, wherein the second circuit condition is an over voltage load.

6. The circuit of claim 2, wherein the second circuit condition is an over current.

7. The circuit of claim 2, wherein the second circuit condition is a short circuit.

8. The circuit of claim 1, wherein the driver increases voltage or current supplied to the transistor if the slope is less steep than the target slope.

9. The circuit of claim 1, wherein the driver decreases voltage or current supplied to the transistor if the slope is steeper than the target slope.

10. The circuit of claim 1, wherein the circuit drives a light emitting diode.

11. The circuit of claim 1, wherein the circuit drives a motor.

12. The circuit of claim 1, wherein the slope is a voltage slope.

13. The circuit of claim 1, wherein the slope is a current slope.

14. A method of regulating the slope of a transistor comprising:
comparing the slope of the transistor to a target slope using a comparator; and
increasing or decreasing voltage or current supplied to the transistor at most once per pulse cycle until the slope reaches the target slope.

15. The method of claim 14, wherein comparing the slope further comprises simultaneously tracking a second circuit condition different from the slope using the comparator.

16. The method of claim 15, wherein the second circuit condition is selected from the group consisting of: an under load, an open load, an over voltage load, an over current, and a short circuit.

17. The method of claim 14, wherein increasing or decreasing voltage or current supplied to the transistor comprises increasing voltage or current supplied to the transistor if the slope is less steep than the target slope.

18. The method of claim 14, wherein increasing or decreasing voltage or current supplied to the transistor comprises decreasing voltage or current supplied to the transistor if the slope is steeper than the target slope.

19. The method of claim 14, wherein the slope is a voltage slope.

20. The method of claim 14, wherein the slope is a current slope.
